(19) United States
(12) Patent Application Publication
(10) Pub. No.: US 2025/0234598 A1
(43) Pub. Date: Jul. 17, 2025

(54) COMBINATION STRUCTURE OF SEMICONDUCTOR DEEP TRENCH DEVICES AND MANUFACTURING METHOD THEREOF

(71) Applicant: Richtek Technology Corporation, Hsinchu (TW)

(72) Inventors: Chin-Chin Tsai, Tainan (TW); Han-Chung Tai, Hsinchu (TW); Yong-Zhong Hu, Hsinchu (TW)

(21) Appl. No.: 18/666,604

(22) Filed: May 16, 2024

(30) Foreign Application Priority Data
Jan. 15, 2024 (TW) 113101581

(51) Int. Cl. H01L 29/06; H01L 27/02; H01L 27/08; H01L 29/66; H01L 29/94

(52) U.S. Cl. CPC H10D 62/102; H10D 1/047; H10D 1/665; H10D 84/212; H10D 89/10

(57) ABSTRACT

A combination structure of semiconductor deep trench devices includes: a deep trench insulator device, which includes at least one deep trench ring unit, wherein the deep trench ring unit includes: a deep trench ring, a first dielectric side wall layer and a first poly silicon fill region; and a deep trench capacitor device, which includes a plurality of deep trench capacitor units and a cathode, wherein each of the deep trench capacitor units includes: a deep trench hole; a second dielectric side wall layer; and a second poly silicon fill region. The deep trench hole is formed by etching a semiconductor substrate with a same etch process step with the deep trench ring. The first dielectric side wall layer and the second dielectric side wall layer is formed by a same oxide growth process step.

### CROSS REFERENCE

The present invention claims priority to TW 113101581 filed on Jan. 15, 2024.

### BACKGROUND OF THE INVENTION

### Field of Invention

The present invention relates to a combination structure of semiconductor deep trench devices and a manufacturing method thereof; particularly, it relates to such combination structure of semiconductor deep trench devices and manufacturing method thereof that can increase isolation voltage and increase capacitance per unit area.

### Description of Related Art

Please refer to FIG. 1, which illustrates a schematic diagram of a prior art including two semiconductor deep trench devices. Due to electrical parameters required, the prior art semiconductor deep trench devices cannot share a same process steps simultaneously. The conventional approach only allows completing the deep trench insulator device 101 and capacitor device 102 using different process steps separately. Therefore, to form both structures, it requires twice amount of photomasks and process steps, and it is necessary to consider whether the double processing causes severe loading effects.

In view of this, the present invention proposes a combination structure of a semiconductor deep trench devices and a manufacturing method thereof, which can solve the above problems and can increase both isolation voltage and capacitance per unit area.

### SUMMARY OF THE INVENTION

From one perspective, the present invention provides a combination structure of semiconductor deep trench devices formed within a semiconductor substrate, comprising: a deep trench insulator device surrounding a high-voltage area and electrically insulating the high-voltage area from exterior of the deep trench insulator device, wherein the deep trench insulator device includes at least one deep trench ring unit, each of the at least one deep trench ring unit including: a deep trench ring formed by a vertical etching process step etching the semiconductor substrate, wherein the deep trench ring appears polygonal in a top view; a first dielectric sidewall layer formed and completely covering a bottom and sidewalls inside the deep trench ring by an oxidation growth process step; and a first polysilicon fill region formed and filling an internal space of the first dielectric sidewall layer with polysilicon material by a depositing process step; and a deep trench capacitor device including a plurality of deep trench capacitor units and a cathode, wherein each of the deep trench capacitor units includes: a deep trench hole formed by the same vertical etching process as step the deep trench ring, vertically etching the semiconductor substrate, wherein the deep trench hole appears circular in a top view; a second dielectric sidewall layer formed by the same oxidation growth process step as the first dielectric sidewall layer, and completely covering a bottom and sidewalls inside the deep trench hole; a second polysilicon fill region formed by the same deposition process step as the first polysilicon fill region, filling an internal space of the second dielectric sidewall layer with polysilicon material; and an anode formed and connected to the second polysilicon fill region, serving as one of positive electrode contacts for the deep trench capacitor device; wherein the cathode is formed on the semiconductor substrate outside the plural deep trench capacitor units, serving as a negative electrode contact for the deep trench capacitor device.

In one embodiment, the plural deep trench capacitor units are arranged in a body-centered cubic packing, face-centered cubic packing, or hexagonal close packing projection on a horizontal plane in a top view.

In one embodiment, the number of the at least one deep trench ring unit is plural and the plural deep trench ring units appear as concentric multilayered arrangement in a top view.

In one embodiment, the deep trench capacitor device further includes a first N-type well region formed in the semiconductor substrate, electrically connected to the cathode and connected to an external surface of the second dielectric sidewall layer of each of the plural deep trench capacitor unit.

In one embodiment, the deep trench capacitor device further includes a first N-type buried region formed below the first N-type well region in the semiconductor substrate, electrically connected to the first N-type well region, and connected to an external surface of the second dielectric sidewall layer of each of the plural deep trench capacitor units.

In one embodiment, the deep trench capacitor unit further includes a first shallow trench insulator region formed at the uppermost exterior of the deep trench hole.

In one embodiment, the deep trench insulator device further includes a second N-type well region formed in the semiconductor substrate, surrounding an exterior of the at least one deep trench ring unit.

In one embodiment, the deep trench insulator device further includes a second N-type buried region formed below the second N-type well region in the semiconductor substrate, surrounding the exterior of the at least one deep trench ring unit.

In one embodiment, the deep trench ring unit further includes two second shallow trench insulator regions, respectively formed at each uppermost exterior on both sides of the deep trench ring.

From another perspective, the present invention provides a manufacturing method of a combination structure of semiconductor deep trench devices, comprising: simultaneously forming a deep trench ring and a deep trench hole by vertically etching a semiconductor substrate with a vertical etching process step, wherein the deep trench ring appears polygonal and the deep trench hole appears circular a top view; simultaneously forming a first dielectric sidewall layer and a second dielectric sidewall layer with an oxidation growth process step, wherein the first dielectric sidewall layer is formed and completely covers the bottom and sidewalls inside the deep trench ring, and the second dielectric sidewall layer is formed and completely covers the bottom and sidewalls inside the deep trench hole; simultaneously forming a first polysilicon fill region and a second polysilicon fill region by a depositing process step, wherein the depositing process step fills an internal space of the first dielectric sidewall layer with polysilicon material to, and fills an internal space of the second dielectric sidewall layer with polysilicon material; and forming an anode and connecting it to the second polysilicon fill region; wherein the deep trench ring, the first dielectric sidewall layer, and the first polysilicon fill region form a deep trench ring unit, wherein at least one of the deep trench ring unit constitutes a deep trench insulator device; wherein the deep trench insulator device surrounds a high-voltage area and electrically insulates the high-voltage area from exterior of the deep trench insulator device; wherein the deep trench hole, the second dielectric sidewall layer, the second polysilicon fill region, and the anode form a deep trench capacitor unit, wherein a plurality of the deep trench capacitor units and a cathode constitute a deep trench capacitor device; wherein the anode serves as one of positive electrode contacts for the deep trench capacitor device; wherein the cathode is formed on the semiconductor substrate outside the plural deep trench capacitor units, serving as a negative electrode contact for the deep trench capacitor device.

In one embodiment, the manufacturing method further comprises simultaneously forming a first N-type well region and a second N-type well region with a same process step; wherein the first N-type well region is formed in the semiconductor substrate, electrically connected to the cathode, and connected to an external surface of the second dielectric sidewall layer of each of the plural deep trench capacitor units; wherein the second N-type well region is formed in the semiconductor substrate, surrounding exterior of the at least one deep trench ring unit.

In one embodiment, the manufacturing method further comprises: simultaneously forming a first N-type buried region and a second N-type buried region with a same process step; wherein the first N-type buried region is formed below the first N-type well region in the semiconductor substrate, electrically connected to the first N-type well region, and connected to the external surface of the second dielectric sidewall layer of each of the plural deep trench capacitor units; wherein the second N-type buried region is formed below the second N-type well region in the semiconductor substrate, surrounding the exterior of the at least one deep trench ring unit.

In one embodiment, the manufacturing method further comprises: simultaneously a forming first shallow trench insulator region and two second shallow trench insulator regions with a same process step; wherein the first shallow trench insulator region is formed at uppermost exterior of the deep trench hole; wherein the two second shallow trench insulator regions are respectively formed at each uppermost exterior on both sides of the deep trench ring.

In one embodiment, the manufacturing method further comprises: after forming the first polysilicon fill region and the second polysilicon fill region, planarizing an upper surface of the semiconductor substrate by a chemical mechanical polishing process step.

In one embodiment, the manufacturing method further comprises: after forming the first shallow trench insulator region and the two second shallow trench insulator regions, planarizing an upper surface of the semiconductor substrate by a chemical mechanical polishing process step.

The objectives, technical details, features, and effects of the present invention will be better understood with regard to the detailed description of the embodiments below, with reference to the attached drawings.

### BRIEF DESCRIPTION OF THE DRAWINGS

FIG. 1 is a schematic diagram showing a prior art semiconductor deep trench devices.

FIG. 2A is a top view schematic diagram of a deep trench insulator device of a combination structure of semiconductor deep trench devices according to an embodiment of the present invention.

FIG. 2B is a top view schematic diagram of a deep trench capacitor device of a combination structure of semiconductor deep trench devices according to another embodiment of the present invention.

FIG. 2C is a cross-sectional schematic diagram of a combination structure of semiconductor deep trench devices according to an embodiment of the present invention.

FIG. 3 is a top view schematic diagram of a deep trench insulator device of a combination structure of semiconductor deep trench devices according to another embodiment of the present invention.

FIG. 4A is a top view schematic diagram of a deep trench capacitor device of a combination structure of semiconductor deep trench devices according to another embodiment of the present invention.

FIG. 4B is a top view schematic diagram of a deep trench capacitor device of a combination structure of semiconductor deep trench devices according to yet another embodiment of the present invention.

FIG. 4C is a top view schematic diagram of a deep trench capacitor device of a combination structure of semiconductor deep trench devices according to a further embodiment of the present invention.

FIG. 5 is a flowchart schematic diagram of the manufacturing method for a combination structure of semiconductor deep trench devices according to an embodiment of the present invention.

FIGS. 6A-6K are cross-sectional schematic views showing a manufacturing method of a combination structure of semiconductor deep trench devices according to an embodiment of the present invention.

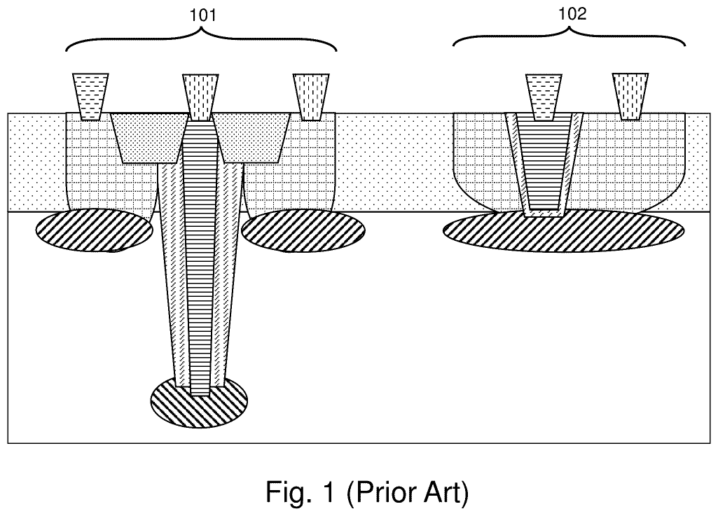

### DESCRIPTION OF THE PREFERRED EMBODIMENTS

The drawings as referred to throughout the description of the present invention are for illustration only, to show the interrelations among the process steps and the layers, while the shapes, thicknesses, and widths are not drawn in actual scale.

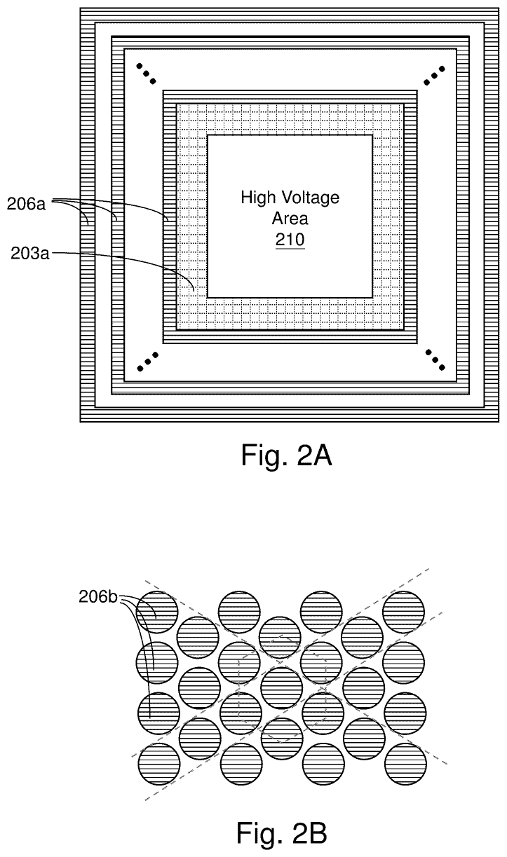

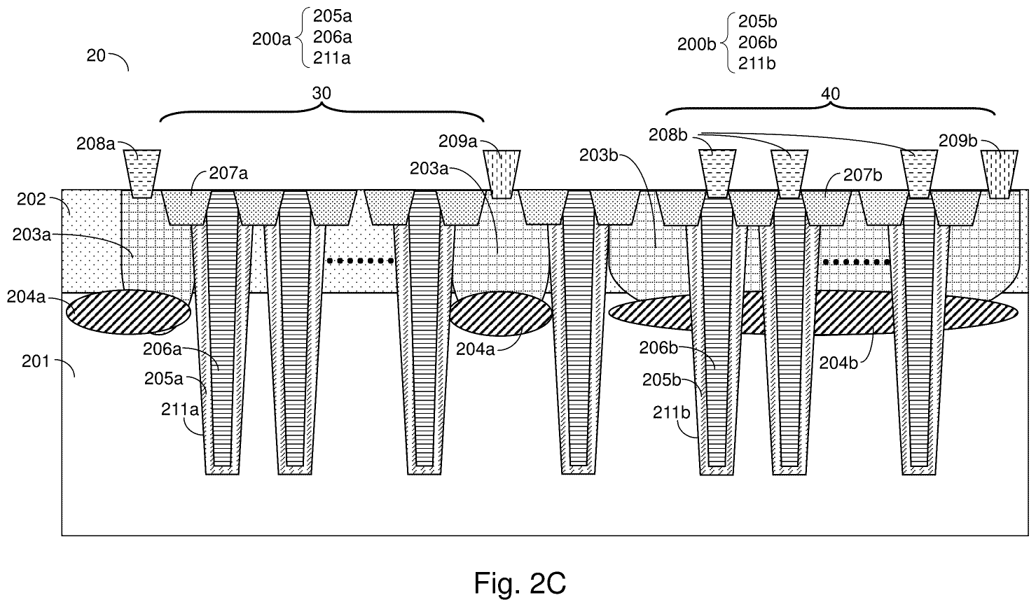

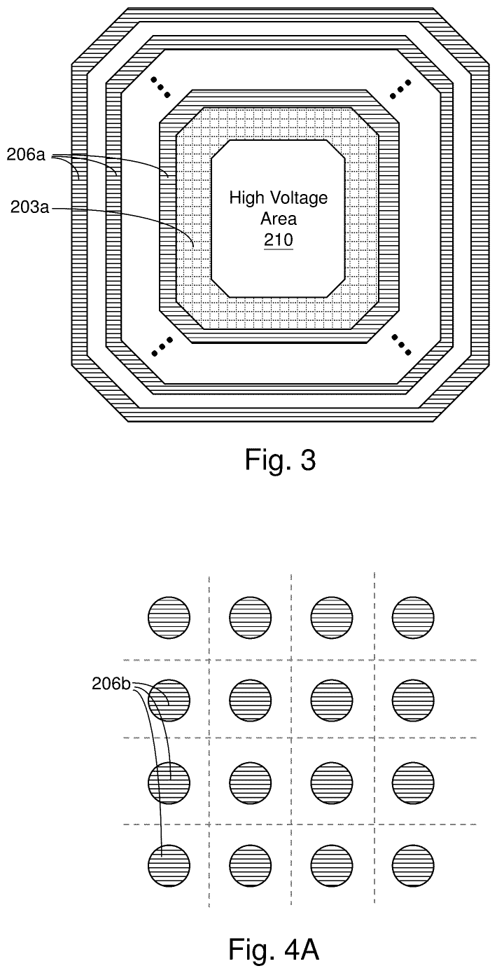

FIG. 2A is a top view schematic diagram showing a deep trench insulator device of a combination structure of semiconductor deep trench devices according to an embodiment of the present invention. As shown in FIG. 2A, there are plural deep trench ring units, arranged in concentric multilayers in a top view. FIG. 3 is a top view schematic diagram of a deep trench insulator device of the combination structure of semiconductor deep trench devices according to another embodiment of the present invention. In one embodiment, as shown in FIGS. 2A and 3, deep trench rings are polygonal in a top view. FIG. 2B is a top view schematic diagram of a deep trench capacitor device of the combination structure of semiconductor deep trench devices according to another embodiment of the present invention. As shown in FIG. 2B, the deep trench capacitor device includes plural deep trench holes; these are circular in a top view.

FIG. 2C is a cross-sectional schematic diagram showing the combination structure of semiconductor deep trench devices according to an embodiment of the present invention. As shown in FIG. 2C, a combination structure of semiconductor deep trench devices 20 is formed within a semiconductor substrate 201. The combination structure of semiconductor deep trench devices 20 includes a deep trench insulator device 30 and a deep trench capacitor device 40. As shown in FIG. 2A, the deep trench insulator device 30 surrounds a high voltage area 210, and electrically insulates the high voltage area 210 from exterior of the deep trench insulator device 30 by the deep trench insulator device 30. Referring to FIG. 2C, the deep trench insulator device 30 includes at least one deep trench ring unit 200a. Each of the at least one deep trench ring units 200a includes a deep trench ring 211a, a dielectric sidewall layer 205a, and a polysilicon fill region 206a.

The deep trench ring 211a is formed by vertically etching the semiconductor substrate 201 through for example but not limited to a vertical etching process step. The dielectric sidewall layer 205a is formed by for example but not limited to an oxidation growth process step, and completely covers interior bottom and sidewalls of the deep trench ring 211a. The polysilicon fill region 206a is formed by for example but not limited to a depositing process step which deposits polysilicon material into an internal space of the dielectric sidewall layer 205a. The deep trench insulator device 30 further includes an N-type well region 203a, formed in the semiconductor substrate 201. The N-type well region 203a surrounds the exterior of at least one deep trench ring unit 200a. The deep trench insulator device 30 further includes an N-type buried region 204a, formed below the N-type well region 203a in the semiconductor substrate 201. The N-type buried region 204a surrounds exterior of at least one deep trench ring unit 200a. The deep trench ring unit 200a further includes two shallow trench insulator regions 207a, each formed at each uppermost exterior on both sides of the deep trench ring 211a.

As shown in FIG. 2C, the deep trench capacitor device 40 includes plural deep trench capacitor units 200b and a cathode 209. Each of the plural deep trench capacitor units 200b includes a deep trench hole 211b, a dielectric sidewall layer 205b, and a polysilicon fill region 206b. The deep trench hole 211b is formed simultaneously with the deep trench ring 211a by the same vertical etching process step, vertically etching the semiconductor substrate 201. As shown in FIG. 2B, the deep trench hole 211b is circular in a top view. Referring to FIG. 2C, the dielectric sidewall layer 205b is formed by the same oxidation growth process step as the dielectric sidewall layer 205a, and completely covers interior bottom and sidewalls of the deep trench hole 211b.

The polysilicon fill region 206b is formed simultaneously with the polysilicon fill region 206a by the same deposition process step, filling an internal space of the dielectric sidewall layer 205b with polysilicon material. The anode 208b is formed and connected on the polysilicon fill region 206b, serving as one of positive electrode contacts for the deep trench capacitor device 40. The cathode 209 is formed on the semiconductor substrate 201 outside the plural deep trench capacitor units 200b, serving as a negative electrode contact for the deep trench capacitor device 40. The deep trench capacitor device 40 further includes an N-type well region 203b, formed in the semiconductor substrate 201. The N-type well region 203b is electrically connected to the cathode 209 and is connected to an external surface of to the dielectric sidewall layer 205b of each of the plural deep trench capacitor units 200b. The deep trench capacitor device 40 further includes an N-type buried region 204b, formed below the N-type well region 203b in the semiconductor substrate 201. The N-type buried region 204b is electrically connected to the N-type well region 203b and is connected to an external surface of the dielectric sidewall layer 205b of each of the plural deep trench capacitor units 200b. The deep trench capacitor unit 200b further includes a shallow trench insulator region 207b, formed at the uppermost exterior of the deep trench hole 211b.

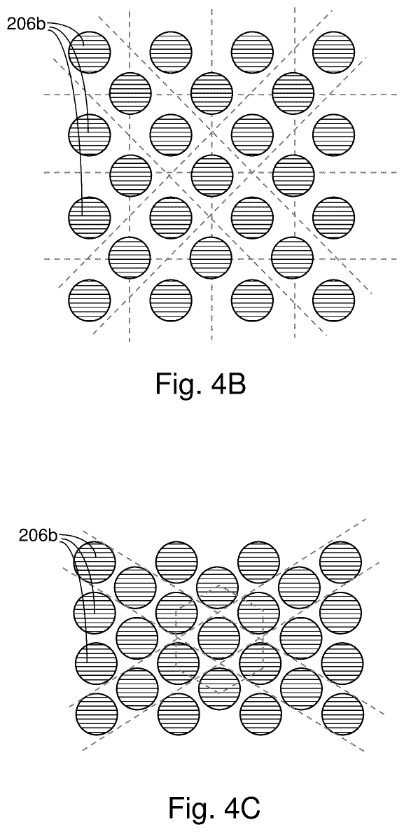

FIG. 4A is a top view schematic diagram of a deep trench capacitor device of the combination structure of semiconductor deep trench devices according to another embodiment of the present invention. As shown in FIG. 4A, in one embodiment, the plural deep trench capacitor units 200b are arranged in a body-centered cubic packing projection on a horizontal plane in a top view. FIG. 4B is a top view schematic diagram of a deep trench capacitor device of the combination structure of semiconductor deep trench devices according to yet another embodiment of the present invention. As shown in FIG. 4B, in another embodiment, the plural deep trench capacitor units 200b are arranged in a face-centered cubic packing projection on a horizontal plane in a top view. FIG. 4C is a top view schematic diagram of a deep trench capacitor device of the combination structure of semiconductor deep trench devices according to a further embodiment of the present invention. As shown in FIG. 4C, in yet another embodiment, the plural deep trench capacitor units 200b are arranged in a hexagonal close packing projection on a horizontal plane in a top view. These various arrangements can increase the capacitance per unit area of the trench capacitors.

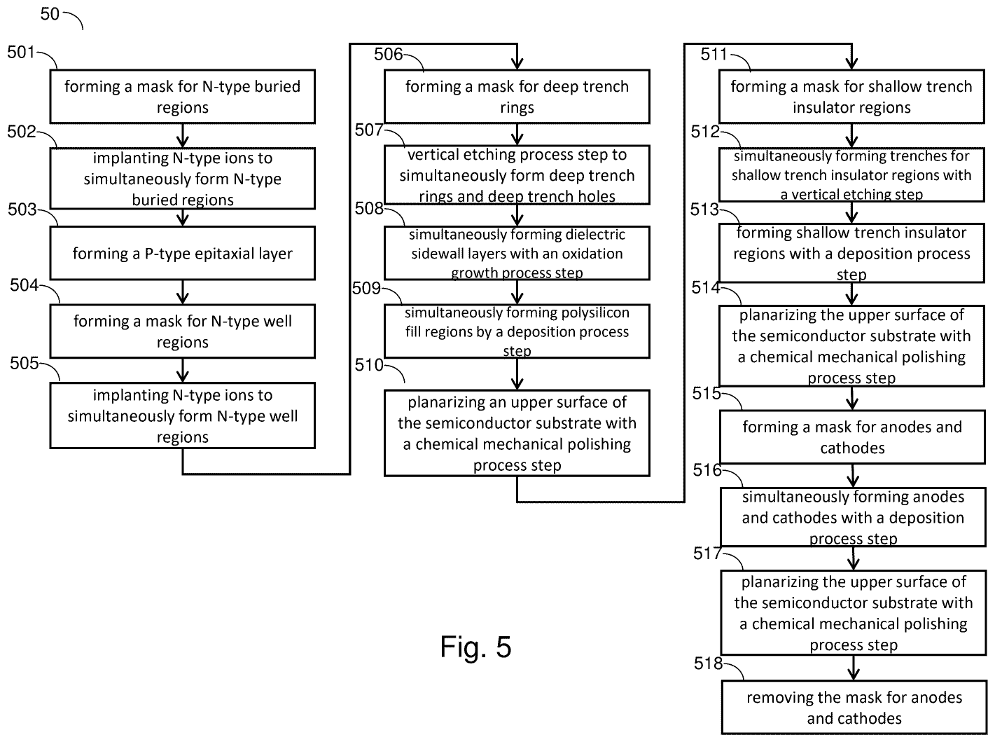

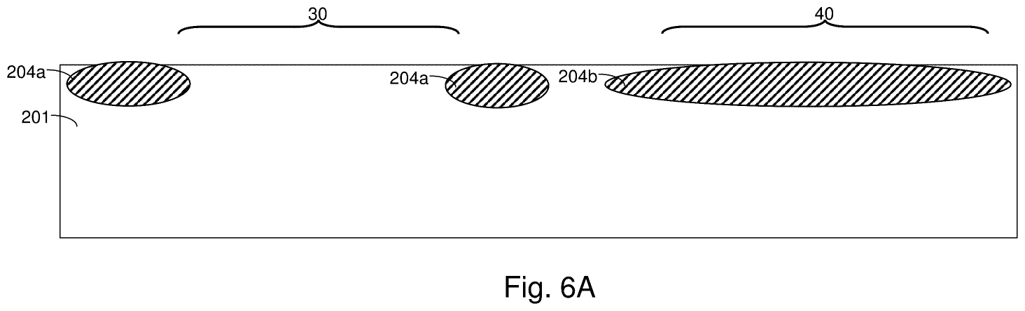

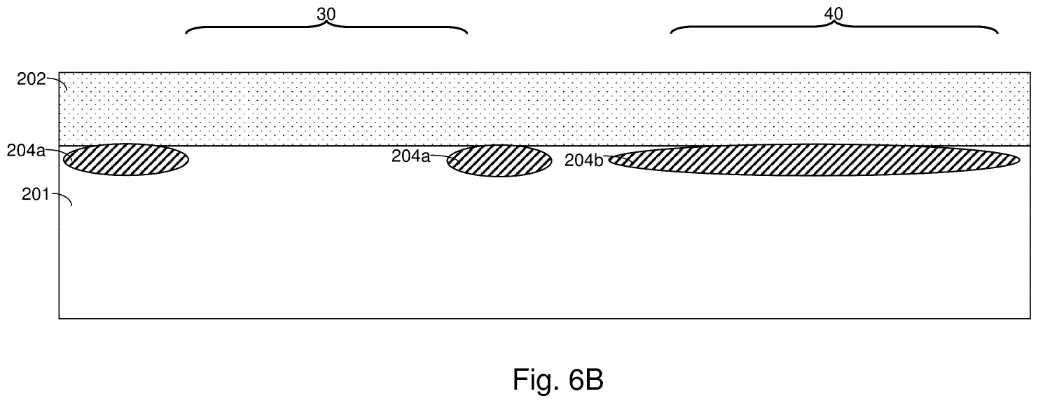

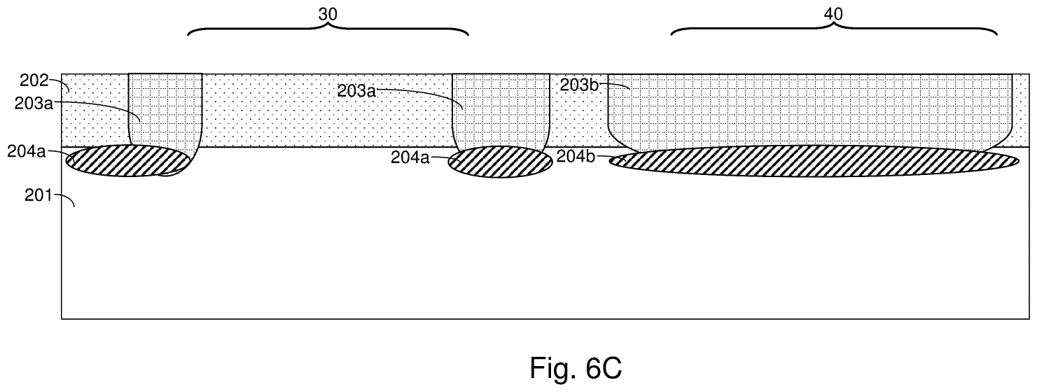

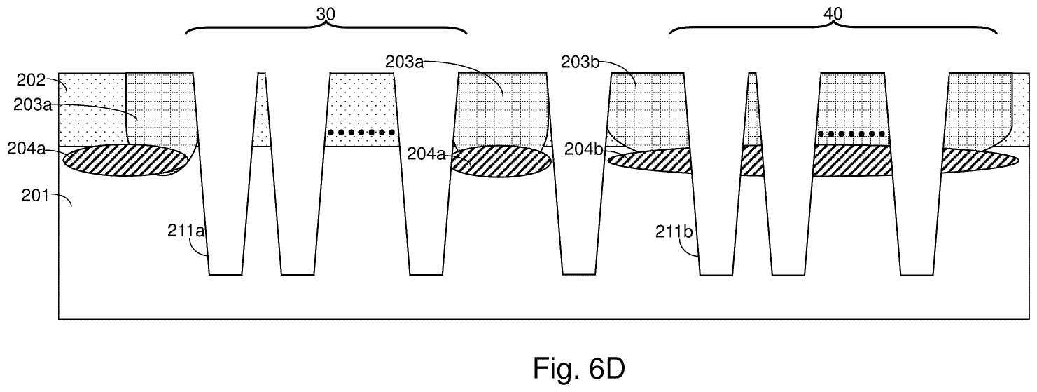

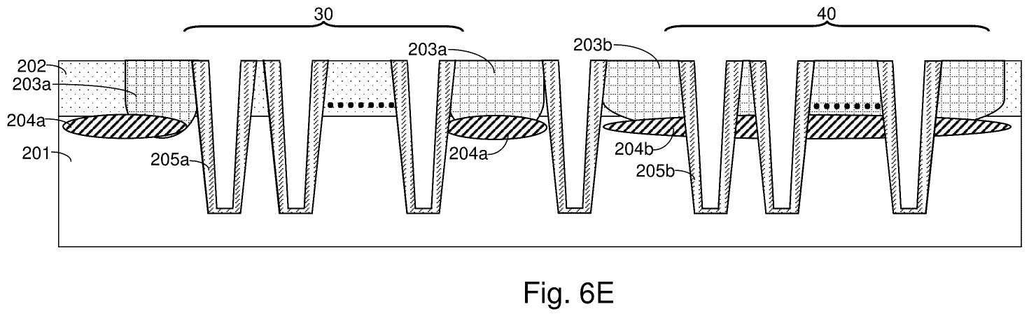

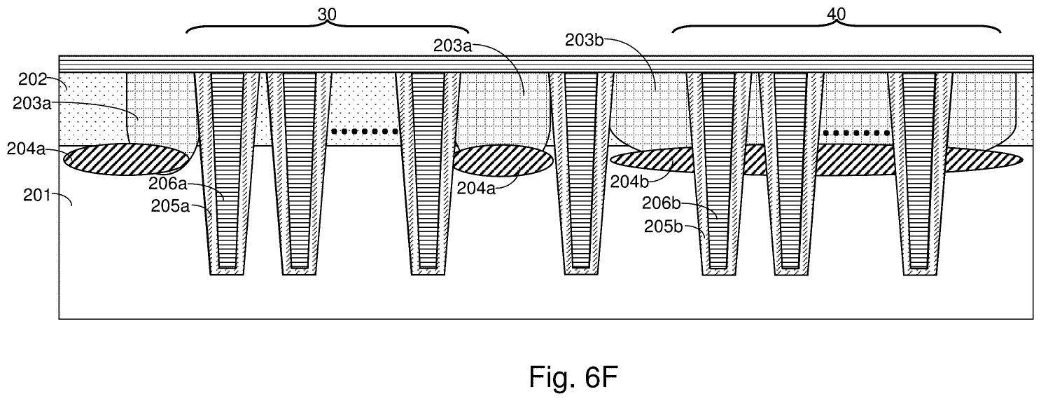

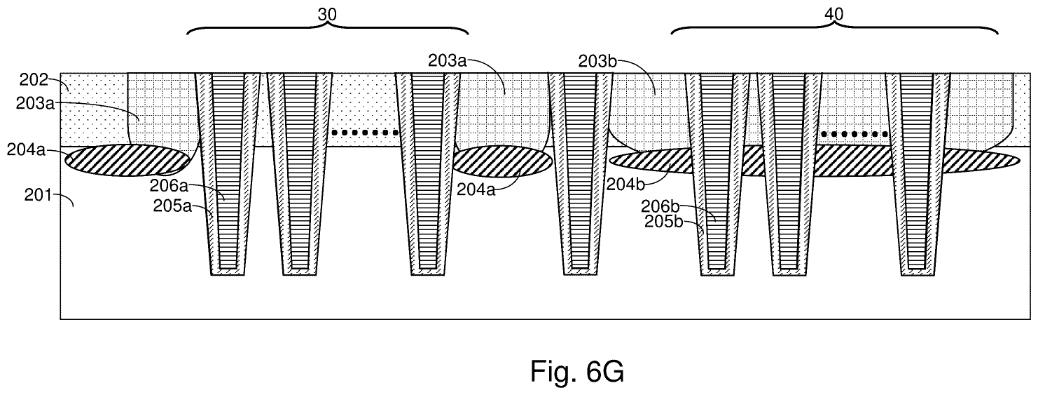

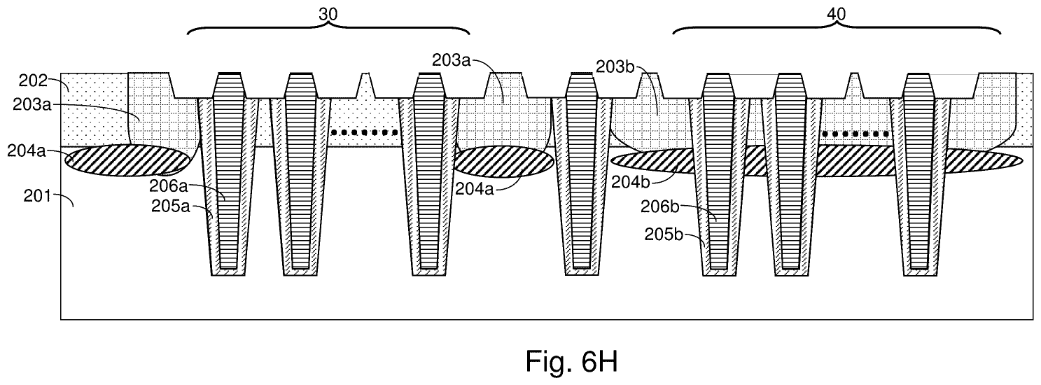

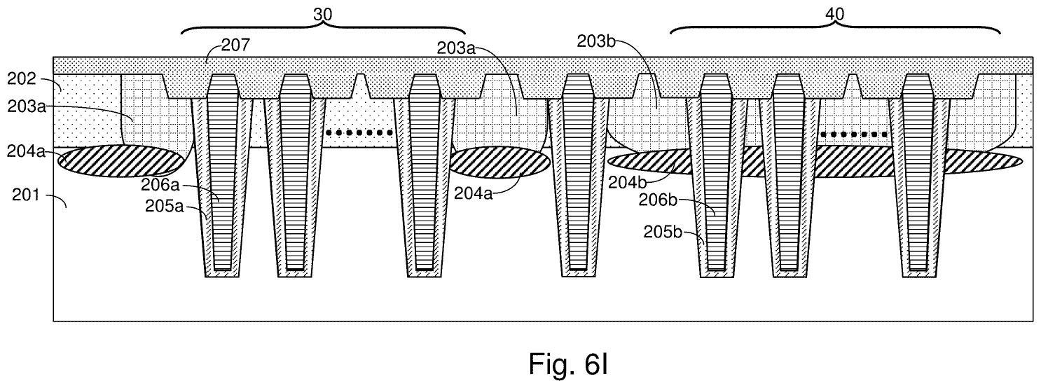

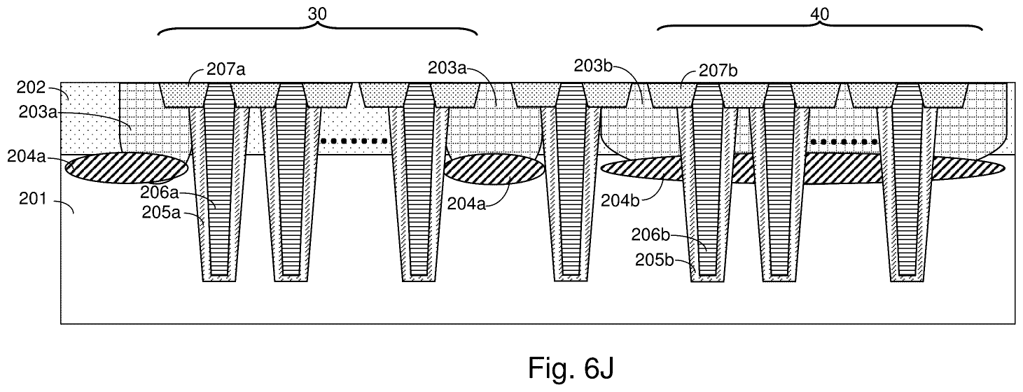

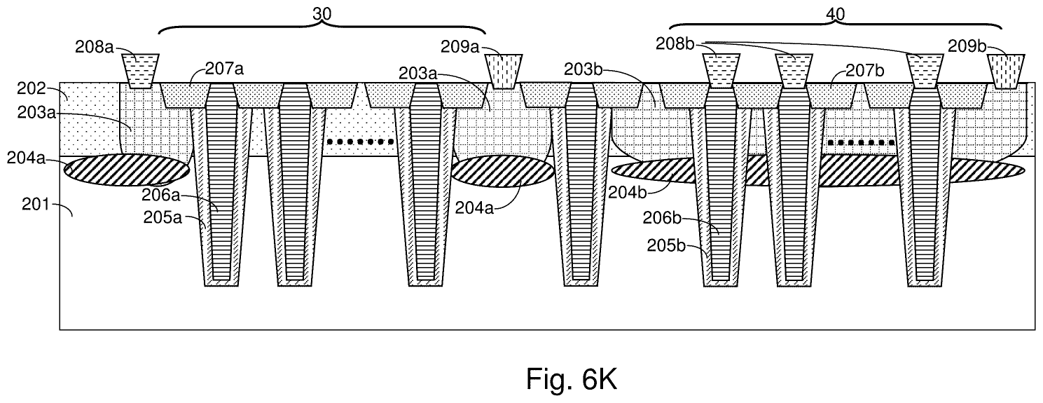

FIG. 5 is a flowchart schematic of the manufacturing method for the combination structure of semiconductor deep trench devices according to an embodiment of the present invention. FIGS. 6A-6K are sectional schematic views showing the manufacturing method of the combination structure of semiconductor deep trench devices according to an embodiment of the present invention. As shown in FIG. 5 and FIG. 6A, the manufacturing method for the combination structure of semiconductor deep trench devices 50 includes step 501, which is forming a mask for N-type buried regions 204a and 204b. Then, step 502 is implanting N-type ions to simultaneously form N-type buried regions 204a and 204b. Subsequently, as shown in FIG. 5 and FIG. 6B, step 503 is forming a P-type epitaxial layer 202. Next, as shown in FIG. 5 and FIG. 6C, step 504 is forming a mask for N-type well regions 203a and 203b. Continuing, step 505 is implanting N-type ions to simultaneously form N-type well regions 203a and 203b.

Then, as shown in FIG. 5 and FIG. 6D, step 506 is forming a mask for deep trench rings 211a and deep trench holes 211b. Next, step 507 is vertically etching the semiconductor substrate with a vertical etching process step to simultaneously form deep trench rings 211a and deep trench holes 211b. Subsequently, as shown in FIG. 5 and FIG. 6E, step 508 is simultaneously forming dielectric sidewall layers 205a and 205b with an oxidation growth process step. Continuing, as shown in FIG. 5 and FIG. 6F, step 509 is simultaneously filling the internal spaces of dielectric sidewall layers 205a and 205b with polysilicon material with a deposition process step to simultaneously form polysilicon fill regions 206a and 206b. Next, as shown in FIG. 5 and FIG. 6G, step 510 is planarizing an upper surface of the semiconductor substrate 201 with a chemical mechanical polishing process step. Subsequently, as shown in FIG. 5 and FIG. 6H, step 511 is forming a mask for shallow trench insulator regions 207a and 207b. Continuing, step 512 is simultaneously forming trenches for shallow trench insulator regions 207a and 207b with a vertical etching step. Next, as shown in FIG. 5 and FIG. 6I, step 513 is simultaneously forming shallow trench insulator regions 207 with a deposition process step.

Then, as shown in FIG. 5 and FIG. 6J, step 514 is planarizing the upper surface of the semiconductor substrate 201 with a chemical mechanical polishing process step to simultaneously form shallow trench insulator regions 207a and 207b. Continuing, as shown in FIG. 5 and FIG. 6K, step 515 is forming a mask for anodes 208a, 208b and cathodes 209a, 209b. Next, step 516 is simultaneously forming anodes 208a, 208b and cathodes 209a, 209b with a deposition process step, connecting anode 208b to the polysilicon fill region 206b. Subsequently, step 517 is planarizing the upper surface of the semiconductor substrate with a chemical mechanical polishing process step to form anodes 208a, 208b and cathodes 209a, 209b. Continuing, step 518 is removing the mask for anodes 208a, 208b and cathodes 209a, 209b.

In summary, the present invention can simultaneously manufacture the deep trench insulator device 30 and the deep trench capacitor device 40, thereby reducing the number of manufacturing steps by half and decreasing the loading effect. Moreover, because the invention adopts a concentric multilayer arrangement of deep trench ring units, it can increase the isolation voltage. Furthermore, the arrangement of the deep trench capacitor units in the invention can increase the capacitance per unit area.

It should be understood that the description is for illustrative purpose, not for limiting the broadest scope of the present invention. An embodiment or a claim of the present invention does not need to achieve all the objectives or advantages of the present invention. The title and abstract are provided for assisting searches but not for limiting the scope of the present invention. Those skilled in this art can readily conceive variations and modifications within the spirit of the present invention. For example, other process steps or structures, such as a light doping drain (LDD) region may be added. For another example, the lithography process step is not limited to the mask technology but it can also include electron beam lithography. It is not limited for each of the embodiments described hereinbefore to be used alone; under the spirit of the present invention, two or more of the embodiments described hereinbefore can be used in combination. For example, two or more of the embodiments can be used together, or, a part of one embodiment can be used to replace a corresponding part of another embodiment. In view of the foregoing, the spirit of the present invention should cover all such and other modifications and variations, which should be interpreted to fall within the scope of the following claims and their equivalents.

What is claimed is:

1. A combination structure of semiconductor deep trench devices formed within a semiconductor substrate, comprising:
a deep trench insulator device surrounding a high-voltage area and electrically insulating the high-voltage area from exterior of the deep trench insulator device, wherein the deep trench insulator device includes at least one deep trench ring unit, each of the at least one deep trench ring unit including:
a deep trench ring formed by a vertical etching process step etching the semiconductor substrate, wherein the deep trench ring appears polygonal in a top view;
a first dielectric sidewall layer formed and completely covering a bottom and sidewalls inside the deep trench ring by an oxidation growth process step; and
a first polysilicon fill region formed and filling an internal space of the first dielectric sidewall layer with polysilicon material by a depositing process step; and
a deep trench capacitor device including a plurality of deep trench capacitor units and a cathode, wherein each of the deep trench capacitor units includes:
a deep trench hole formed by the same vertical etching process step as the deep trench ring, vertically etching the semiconductor substrate, wherein the deep trench hole appears circular in a top view;
a second dielectric sidewall layer formed by the same oxidation growth process step as the first dielectric sidewall layer, and completely covering a bottom and sidewalls inside the deep trench hole;
a second polysilicon fill region formed by the same deposition process step as the first polysilicon fill region, filling an internal space of the second dielectric sidewall layer with polysilicon material; and
an anode formed and connected to the second polysilicon fill region, serving as one of positive electrode contacts for the deep trench capacitor device;
wherein the cathode is formed on the semiconductor substrate outside the plural deep trench capacitor units, serving as a negative electrode contact for the deep trench capacitor device.

2. The combination structure of semiconductor deep trench devices as claimed in claim 1, wherein the plural deep trench capacitor units are arranged in a body-centered cubic packing, face-centered cubic packing, or hexagonal close packing projection on a horizontal plane in a top view.

3. The combination structure of semiconductor deep trench devices as claimed in claim 1, wherein the number of the at least one deep trench ring unit is plural and the plural deep trench ring units appear as arranged in concentric multilayers in a top view.

4. The combination structure of semiconductor deep trench devices as claimed in claim 1, wherein the deep trench capacitor device further includes a first N-type well region formed in the semiconductor substrate, electrically connected to the cathode and connected to an external surface of the second dielectric sidewall layer of each of the plural deep trench capacitor units.

5. The combination structure of semiconductor deep trench devices as claimed in claim 4, wherein the deep trench capacitor device further includes a first N-type buried region formed below the first N-type well region in the semiconductor substrate, electrically connected to the first N-type well region, and connected to an external surface of the second dielectric sidewall layer of each of the plural deep trench capacitor units.

6. The combination structure of semiconductor deep trench devices as claimed in claim 1, wherein the deep trench capacitor unit further includes a first shallow trench insulator region formed at the uppermost exterior of the deep trench hole.

7. The combination structure of semiconductor deep trench devices as claimed in claim 1, wherein the deep trench insulator device further includes a second N-type well region formed in the semiconductor substrate, surrounding an exterior of the at least one deep trench ring unit.

8. The combination structure of semiconductor deep trench devices as claimed in claim 7, wherein the deep trench insulator device further includes a second N-type buried region formed below the second N-type well region in the semiconductor substrate, surrounding the exterior of the at least one deep trench ring unit.

9. The combination structure of semiconductor deep trench devices as claimed in claim 1, wherein the deep trench ring unit further includes two second shallow trench insulator regions, respectively formed at each uppermost exterior on both sides of the deep trench ring.

10. A manufacturing method of a combination structure of semiconductor deep trench devices, comprising:
simultaneously forming a deep trench ring and a deep trench hole by vertically etching a semiconductor substrate with a vertical etching process step, wherein the deep trench ring appears polygonal and the deep trench hole appears circular in a top view;
simultaneously forming a first dielectric sidewall layer and a second dielectric sidewall layer with an oxidation growth process step, wherein the first dielectric sidewall layer is formed and completely covers the bottom and sidewalls inside the deep trench ring, and the second dielectric sidewall layer is formed and completely covers the bottom and sidewalls inside the deep trench hole;
simultaneously forming a first polysilicon fill region and a second polysilicon fill region by a depositing process step, wherein the depositing process step fills an internal space of the first dielectric sidewall layer with polysilicon material to, and fills an internal space of the second dielectric sidewall layer with polysilicon material; and
forming an anode and connecting it to the second polysilicon fill region;
wherein the deep trench ring, the first dielectric sidewall layer, and the first polysilicon fill region form a deep trench ring unit, wherein at least one of the deep trench ring unit constitutes a deep trench insulator device;
wherein the deep trench insulator device surrounds a high-voltage area and electrically insulates the high-voltage area from exterior of the deep trench insulator device;
wherein the deep trench hole, the second dielectric sidewall layer, the second polysilicon fill region, and the anode form a deep trench capacitor unit, wherein a plurality of the deep trench capacitor units and a cathode constitute a deep trench capacitor device;
wherein the anode serves as one of positive electrode contacts for the deep trench capacitor device;
wherein the cathode is formed on the semiconductor substrate outside the plural deep trench capacitor units, serving as a negative electrode contact for the deep trench capacitor device.

11. The manufacturing method of a combination structure of semiconductor deep trench devices as claimed in claim 10, wherein the plural deep trench capacitor units are arranged in a body-centered cubic packing, face-centered cubic packing, or hexagonal close packing projection on a horizontal plane in a top view.

12. The manufacturing method of a combination structure of semiconductor deep trench devices as claimed in claim 10, wherein the number of the at least one deep trench ring unit is plural and the plural deep trench ring units appear as concentric multilayered arrangement in a top view.

13. The manufacturing method of a combination structure of semiconductor deep trench devices as claimed in claim 10, further comprising:
simultaneously forming a first N-type well region and a second N-type well region with a same process step;
wherein the first N-type well region is formed in the semiconductor substrate, electrically connected to the cathode, and connected to an external surface of the second dielectric sidewall layer of each of the plural deep trench capacitor units;
wherein the second N-type well region is formed in the semiconductor substrate, surrounding exterior of the at least one deep trench ring unit.

14. The manufacturing method of a combination structure of semiconductor deep trench devices as claimed in claim 13, further comprising:
simultaneously forming a first N-type buried region and a second N-type buried region with a same process step;
wherein the first N-type buried region is formed below the first N-type well region in the semiconductor substrate, electrically connected to the first N-type well region, and connected to the external surface of the second dielectric sidewall layer of each of the plural deep trench capacitor units;
wherein the second N-type buried region is formed below the second N-type well region in the semiconductor substrate, surrounding the exterior of the at least one deep trench ring unit.

15. The manufacturing method of a combination structure of semiconductor deep trench devices as claimed in claim 10, further comprising:
simultaneously forming a first shallow trench insulator region and two second shallow trench insulator regions with a same process step;
wherein the first shallow trench insulator region is formed at uppermost exterior of the deep trench hole;
wherein the two second shallow trench insulator regions are respectively formed at each uppermost exterior on both sides of the deep trench ring.

16. The manufacturing method of a combination structure of semiconductor deep trench devices as claimed in claim 10, further comprising:
after forming the first polysilicon fill region and the second polysilicon fill region, planarizing an upper surface of the semiconductor substrate by a chemical mechanical polishing process step.

17. The manufacturing method of a combination structure of semiconductor deep trench devices as claimed in claim 15, further comprising:
after forming the first shallow trench insulator region and the two second shallow trench insulator regions, planarizing an upper surface of the semiconductor substrate by a chemical mechanical polishing process step.
